(19) United States
(12) Patent Application Publication
(10) Pub. No.: US 2026/0173265 A1
(43) Pub. Date: Jun. 18, 2026

(54) PRINTED CIRCUIT BOARD

(71) Applicant: SAMSUNG ELECTRO-MECHANICS CO., LTD., Suwon-si (KR)

(72) Inventors: Sang Yun Lee, Suwon-si (KR); Chang Hwa Park, Suwon-si (KR); Sang Ho Jeong, Suwon-si (KR); Hyun Hu Lee, Suwon-si (KR)

(73) Assignee: SAMSUNG ELECTRO-MECHANICS CO., LTD., Suwon-si (KR)

(21) Appl. No.: 19/371,707

(22) Filed: Oct. 28, 2025

(30) Foreign Application Priority Data
Dec. 13, 2024 (KR) 10-2024-0185922

(51) Int. Cl. H05K 1/11; H05K 3/28

(52) U.S. Cl. CPC H05K 1/111; H05K 3/285

(57) ABSTRACT

A printed circuit board includes an insulating layer, a pad portion disposed on the insulating layer, a protective layer disposed on the insulating layer and the pad portion, a conductive post disposed on the pad portion and protruding outwardly, as compared to the protective layer, and an insulating film formed on a portion of a surface of the conductive post.

### CROSS-REFERENCE TO RELATED APPLICATION(S)

This application claims benefit of priority to Korean Patent Application No. 10-2024-0185922 filed on December 13, 2024 in the Korean Intellectual Property Office, the disclosure of which is incorporated herein by reference in its entirety.

### TECHNICAL FIELD

The present disclosure relates to a printed circuit board.

In order to respond to the recent trend of lightening and miniaturizing mobile devices, the need to implement lightening and miniaturization in printed circuit boards mounted thereon has also increased. Meanwhile, as mobile devices become lighter and are miniaturized, an undercut phenomenon may occur during the process of implementing microcircuits, which may cause defects in the microcircuits. In response to the technical demand therefor, research has been conducted to improve reliability, while implementing circuits with fine line widths and spacings.

### SUMMARY

An aspect of the present disclosure is to provide a printed circuit board with improved structural stability of conductive posts or the like.

According to an aspect of the present disclosure, a printed circuit board includes: an insulating layer; a pad portion disposed on the insulating layer; a protective layer disposed on the insulating layer and the pad portion; a conductive post disposed on the pad portion and protruding outwardly, as compared to the protective layer; and an insulating film formed on a portion of a surface of the conductive post.

At least a portion of the insulating film may be interposed between the conductive post and the protective layer.

The insulating film may be in contact with the conductive post and the protective layer.

The insulating film may be formed in at least a portion of a region of a side surface of the conductive post not covered with the protective layer.

At least a portion of an upper surface of the conductive post may be exposed and may not be covered with the insulating film.

The insulating film may also be formed on a surface of the pad portion.

The printed circuit board may further include: a conductive layer disposed on the insulating layer, wherein the insulating film may be also formed on a surface of the conductive layer.

The insulating film may also be formed on an upper surface of the insulating layer.

The insulating film may extend onto surfaces of the pad portion and the insulating layer to form an integral structure as a whole.

The insulating film may have a shape conforming to the surface of the conductive post, the pad portion, and the insulating layer.

The insulating film may be an atomic layer deposition layer.

The insulating film may include Al₂O₃.

The printed circuit board may further include: a conductive cap layer disposed on the conductive post and electrically connected to the conductive post.

The conductive cap layer may be formed in a range not covering a side surface of the conductive post.

The conductive cap layer may be formed in a range not covering a side surface of the insulating film.

According to another aspect of the present disclosure, a printed circuit board includes: an insulating layer; a pad portion disposed on the insulating layer; a protective layer disposed on the insulating layer and the pad portion; a conductive post disposed on the pad portion; and an insulating film formed on a portion of surfaces of the pad portion and the conductive post.

### BRIEF DESCRIPTION OF DRAWINGS

The and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIG. 4 is a plan view illustrating a conductive post and a surrounding region thereof;

FIGS. 5, 6, 7, 8, 9 and 10 illustrate examples of a method of manufacturing a printed circuit board; and

FIG. 11 is a cross-sectional view illustrating a printed circuit board according to a modified example.

FIG. 12 is a cross-sectional view illustrating a printed circuit board according to a modified example.

### DETAILED DESCRIPTION

Hereinafter, embodiments of the present disclosure will be described with reference to specific embodiments and the accompanying drawings. The embodiments of the present disclosure may, however, be exemplified in many different forms and should not be construed as being limited to the specific embodiments set forth herein. Rather, these embodiments are provided so that this disclosure will be thorough and complete, and will fully convey the scope of the inventive concept to those skilled in the art. In the drawings, the shapes and dimensions of elements may be exaggerated for clarity, and the same reference numerals will be used throughout to designate the same or like elements.

### Electronic Device

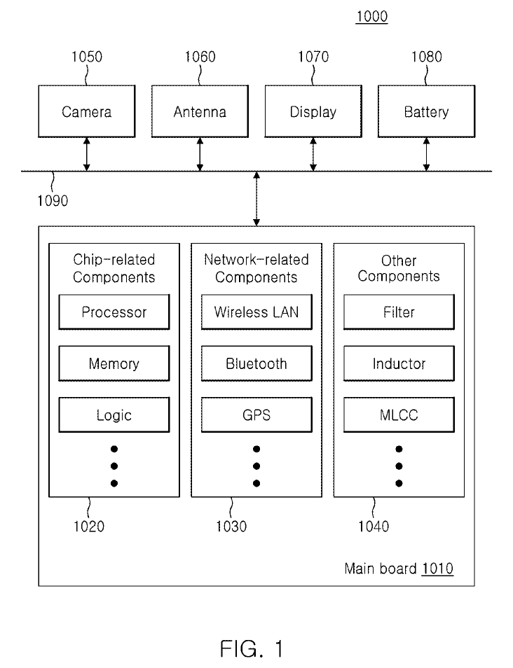

Referring to FIG. 1, an electronic device 1000 accommodates a main board 1010. A chip-related component 1020, a network-related component 1030, and other components 1040 are physically and/or electrically connected to the main board 1010. These components are combined with other electronic components to be described below to form various signal lines 1090.

The chip-related component 1020 includes memory chips, such as volatile memories (e.g., DRAM), nonvolatile memory (e.g., ROM), and flash memories; application processor chips, such as central processors (e.g., CPUs), graphics processors (e.g., GPUs), digital signal processors, encryption processors, microprocessors, and microcontrollers; logic chips, such as analog-to-digital converters (ADCs), and application-specific integrated circuits (ASICs), but is not limited thereto and may include other types of chip-related electronic components as well. In addition, these chip-related components 1020 may be combined with each other. The chip-related component 1020 may be in the form of a package including the aforementioned chip or electronic component.

The network related component 1030 may include Wi-Fi (IEEE 802.11 family, etc.), WiMAX (IEEE 802.16 family, etc.), IEEE 802.20, long term evolution (LTE), Ev-DO, HSPA+, HSDPA+, HSUPA+, EDGE, GSM, GPS, GPRS, CDMA, TDMA, DECT, Bluetooth, 3G, 4G, 5G, and any other wireless and wired protocols designated thereafter, but is not limited to and may include any of other wireless or wired standards or protocols. In addition, the network-related component 1030 and the chip-related component 1020 may be combined with each other.

The other components 1040 include high-frequency inductors, ferrite inductors, power inductors, ferrite beads, low temperature co-firing ceramics (LTCCs), electromagnetic interference (EMI) filters, multi-layer ceramic condensers (MLCCs), and the like. However, the other components 1040 are not limited thereto and may include passive elements in the form of chip components used for various other purposes. In addition, the other components 1040 may be combined with the chip-related component 1020 and/or the network-related component 1030.

Depending on the type of electronic device 1000, the electronic device 1000 may include other electronic components that may or may not be physically and/or electrically connected to the main board 1010. The other electronic components may include, for example, a camera 1050, an antenna 1060, a display 1070, and a battery 1080. However, the electronic components are not limited thereto and may include audio codecs, video codecs, power amplifiers, compasses, accelerometers, gyroscopes, speakers, mass storage devices (e.g., hard disk drives), compact disks (CDs), digital versatile disks (DVDs), etc. In addition, other electronic components used for various purposes may be included depending on the type of the electronic device 1000.

The electronic device 1000 may include smartphones, personal digital assistants (PDAs), digital video cameras, digital still cameras, network systems, computers, monitors, tablets, laptops, netbooks, televisions, video game machines, smart watches, automotive components, and the like. However, the electronic device 1000 is not limited thereto and may be any other electronic device that processes data, in addition thereto.

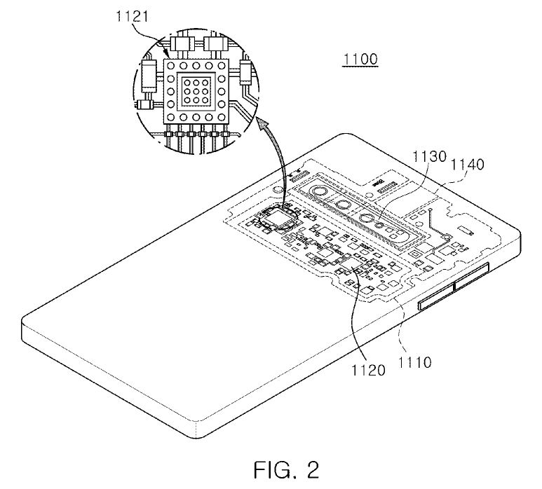

FIG. 2 is a perspective view schematically illustrating an example of an electronic device.

Referring to FIG. 2, the electronic device may be, for example, a smartphone 1100. A motherboard 1110 is accommodated inside the smartphone 1100, and various components 1120 are physically and/or electrically connected to the motherboard 1110. In addition, other components that may or may not be physically and/or electrically connected to the motherboard 1110, such as a camera module 1130 and/or a speaker 1140, are accommodated in the smartphone 1100. Some of the components 1120 may be the aforementioned chip-related components, for example, a component package 1121, but are not limited thereto. The component package 1121 may be a printed circuit board in which electronic components including active components and/or passive components are surface-mounted. Alternatively, the component package 1121 may be in the form of a printed circuit board including active components and/or passive components embedded therein. Meanwhile, the electronic device is not necessarily limited to the smartphone 1100 and may of course be other electronic devices as described above.

### Printed Circuit Board

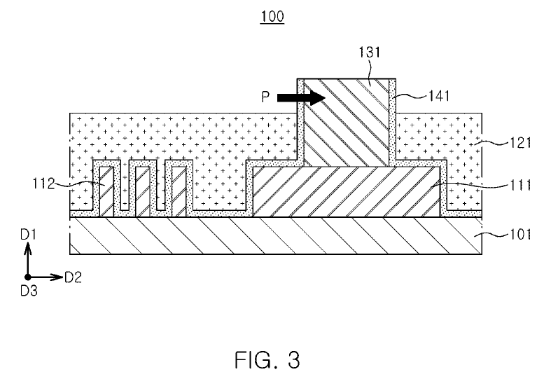

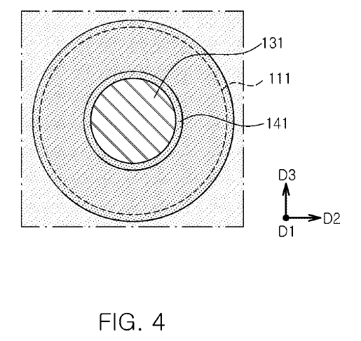

FIG. 3 is a cross-sectional view schematically illustrating an example of a printed circuit board. FIG. 4 is a plan view illustrating a conductive post and a surrounding region. Referring to FIGS. 3 and 4, a printed circuit board 100 according to the present embodiment includes an insulating layer 101, a pad portion 111, a protective layer 121, a conductive post 131, and an insulating film 141. Here, the insulating film 141 is formed on a portion of a surface of the conductive post 131. The conductive post 131 is effectively protected from external force or the like by the insulating film 141, so that structural stability may be improved. In addition, by using the insulating film 141, a surface treatment process for increasing roughness of the surface of the conductive post 131 or pad portion 111 may not be necessary, and thus, signal loss may be reduced. Hereinafter, the main components of the printed circuit board 100 will be described in detail. In the drawings, a first direction D1 may be defined as a thickness direction of the insulating layer 101, and second and third directions D2 and D3 may be defined as directions, perpendicular to the first direction D1 and perpendicular to each other.

The insulating layer 101 may include an insulating material and may be implemented as a multilayer structure. Here, the insulating material of the insulating layer 101 may include a thermosetting resin, such as an epoxy resin, a thermoplastic resin, such as polyimide, or a material, such as an inorganic filler, an organic filler, and/or a glass fiber (glass cloth and/or glass fabric) together with such a resin. The insulating material may be a photosensitive material and/or a non-photosensitive material. For example, as the insulating material, solder resist (SR), Ajinomoto build-up film (ABF), FR-4, bismaleimide triazine (BT), prepreg (PPG), resin coated copper (RCC) insulating material, copper clad laminate (CCL) insulating material, or the like may be used, but are not limited thereto, and other polymer materials may be used in addition.

The pad portion 111 is disposed on the insulating layer 101 and may be provided as a region connected to a semiconductor chip, a package, an interposer, or the like. In this case, at least a portion of the pad portion 111 may also be embedded in the insulating layer 101. As illustrated in FIG. 4, the pad portion 111 may have a cylindrical shape or a shape similar to a cylindrical shape. In addition to the pad portion 111, the printed circuit board 100 may further include a conductive layer 112 on the insulating layer 101. The pad portion 111 and the conductive layer 112 may include a metal having high electrical conductivity, such as copper (Cu), aluminum (Al), silver (Ag), tin (Sn), gold (Au), nickel (Ni), lead (Pb), titanium (Ti), and/or alloys thereof and may be implemented as a multilayer structure, if necessary. In addition, the insulating layer 101 may further include a conductive layer, pad, conductive via, or the like arranged on a different level from those of the pad portion 111 and the conductive layer 112.

The protective layer 121 is disposed on the insulating layer 101 and the pad portion 111 and may protect the pad portion 111, the conductive layer 112, the conductive post 131, or the like. The protective layer 121 may include a solder resist material and may include a photosensitive insulating material as an example.

The conductive post 131 may be disposed on the pad portion 111 and may be provided as a connection region with other printed circuit boards, chips, or the like. As illustrated in FIG. 4, the conductive post 131 may have a cylindrical shape or a cylinder-like shape. The conductive post 131 has a shape protruding outwardly from the protective layer 121, i.e., includes a protrusion P. Here, the shape protruding outwardly from the protective layer 121 means that at least a portion of the conductive post 131 is located farther from the insulating layer 101 than the protective layer 121. In the case of the conductive post 131 having such an externally protruding shape, damage may occur due to external force during handling, driving, etc. of the printed circuit board 100, which may lead to a decrease in the reliability of the printed circuit board 100. In the present embodiment, the insulating film 141 is formed on a portion of the surface of the conductive post 131 so that the conductive post 131 may be protected from external influences, or the like. In this case, as illustrated, at least a portion of the insulating film 141 may be interposed between the conductive post 131 and the protective layer 121. The insulating film 141 may be in contact with the conductive post 131 and the protective layer 121. In addition, the insulating film 141 may be formed in a region of a side surface of the conductive post 131 covered with the protective layer 121, that is, in at least a portion of the protrusion P. Although FIG. 3 illustrates a form in which the insulating film 141 is formed on the entire side surface of the protrusion P, the insulating film 141 may be formed on only a portion of the side surface of the protrusion P.

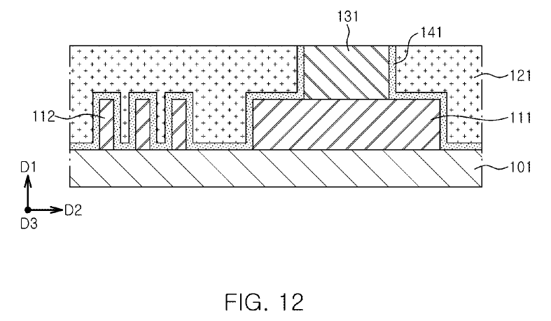

Since the conductive post 131 is provided as a mounting region for a semiconductor chip, or the like, at least a portion of the upper surface of the conductive post 131 may be exposed without being covered with the insulating film 141. In FIG. 3, the entire upper surface of the conductive post 131 is illustrated to be exposed, but a portion of the upper surface of the conductive post 131 may be covered with the insulating film 141. The insulating film 141 may be formed also in a portion of the surface of the pad portion 111 in addition to the conductive post 131, and accordingly, the insulating film 141 may be interposed between the pad portion 111 and the protective layer 121. Since the insulating film 141 is formed on the surface of the pad portion 111, the pad portion 111 may also be effectively protected. When the insulating film 141 is formed on both the surfaces of the conductive post 131 and the pad portion 111, structural stability of the printed circuit board 100 may be significantly improved. In this case, the conductive post 131 may not necessarily have to have the shape including the protrusion P as described in FIG. 12. In some embodiments, an upper surface of the conductive post 131 is exposed and configured to provide an electrical connection to an electronic component.

In addition, the insulating film 141 may also be formed on the surface of the conductive layer 112 to protect the conductive layer 112. In the related art, in order to increase adhesion with the protective layer 121, the surfaces of the conductive post 131, the pad portion 111, the conductive layer 112, or the like were partially etched to increase the roughness, and then the protective layer 121 was formed. However, this may increase signal loss and deteriorate electrical characteristics. In the present embodiment, the insulating film 141 may be employed so that surface treatment of the conductive post 131, the pad portion 111, the conductive layer 112, or the like may not be performed, and even in this case, high adhesion with the protective layer 121 may be obtained. Furthermore, the insulating film 141 may also be formed on an upper surface of the insulating layer 101. In this case, as illustrated, the insulating film 141 may extend to the surfaces of the pad portion 111 and the insulating layer 101 to form an integral structure as a whole, and this integral structure may be implemented in a manner in which the insulating film 141 is formed on the surfaces of the insulating layer 101, the pad portion 111, the conductive layer 112, the conductive post 131, or the like, as a whole, as can be seen in the process described below. In this case, the insulating film 141 may have a shape conforming to the surfaces of the conductive post 131, the pad portion 111, and the insulating layer 101. However, in FIG. 3, the insulating film 141 forms an integral structure as a whole on the surfaces of the pad portion 111, the conductive layer 112, and the conductive post 131, but the insulating film 141 may be formed only on the surface of the conductive post 131. In addition, the insulating film 141 may be formed only on the surfaces of the conductive post 131 and the pad portion 111.

Considering the aforementioned function, it may be appropriate for the insulating film 141 to be implemented thinly, while having high insulation. The insulating film 141 may be applied on a portion of the surface of the conductive post 131. In this case, the insulating film 141 may be an atomic layer deposition layer. As a more specific example, the insulating film 141 may include Al₂O₃. Alternatively, the insulating film 141 may be a surface oxide layer of the conductive post 131.

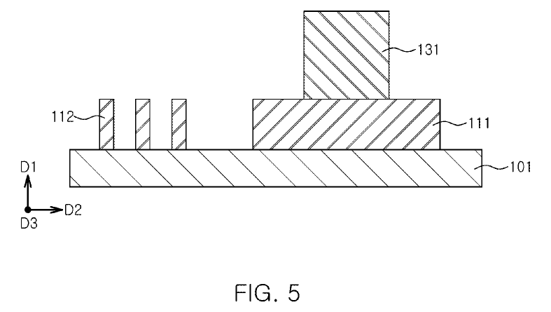

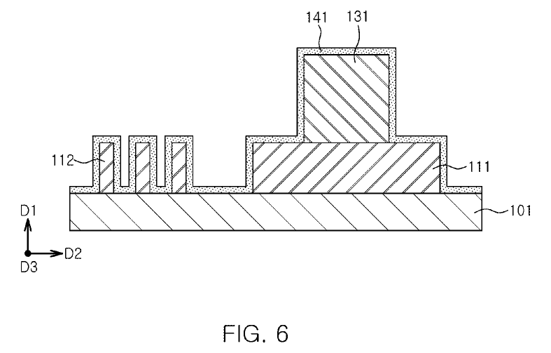

Hereinafter, a method of manufacturing a printed circuit board will be described with reference to FIGS. 5 to 10. The following description will focus on a method of forming the insulating film 141, and general knowledge of manufacturing a printed circuit board may be utilized for other components. First, the pad portion 111, the conductive layer 112, and the conductive post 131 are formed on the insulating layer 101 (FIG. 5). Thereafter, the insulating film 141 is formed to entirely cover the pad portion 111, the conductive layer 112, and the conductive post 131 (FIG. 6). As an example of the process, the insulating film 141 may be formed by an atomic layer deposition process. However, the insulating film 141 may be formed using another deposition process. In this case, the insulating film 141 may be formed in a shape conforming to the surfaces of the pad portion 111, the conductive layer 112, the conductive post 131, or the like. As described above, surface treatment for increasing the roughness of the pad portion 111, the conductive layer 112, and the conductive post 131 may not be performed before forming the insulating film 141, and thus, signal loss due to a decrease in the size of a circuit pattern may be reduced.

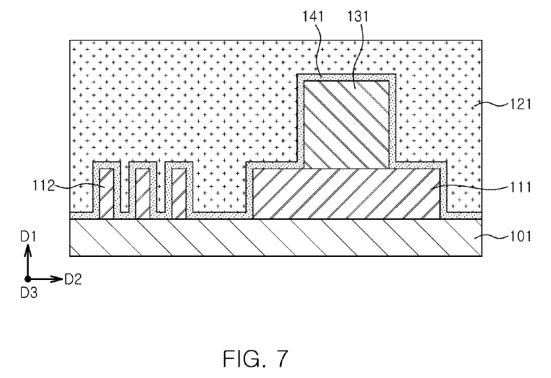

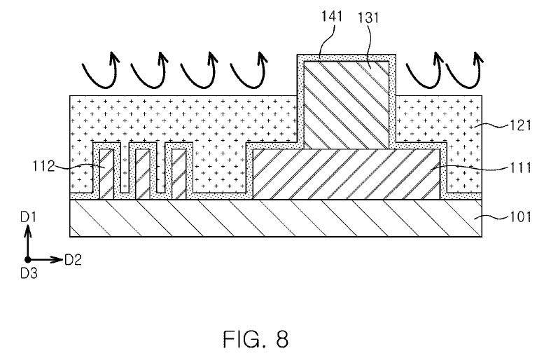

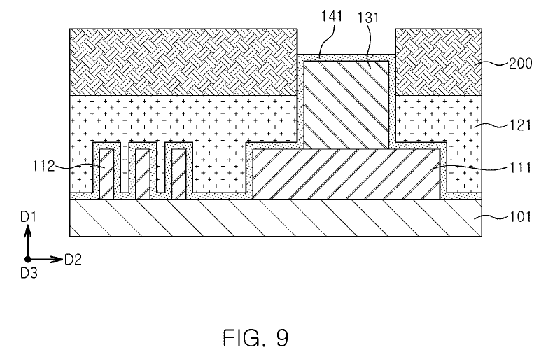

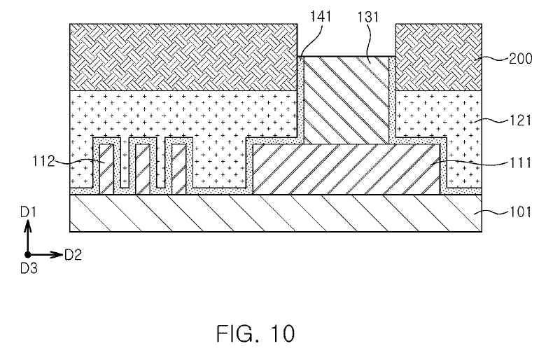

Subsequently, the protective layer 121 is formed on the insulating film 141 (FIG. 7), and here, the protective layer 121 may be formed to have a thickness to cover the upper surface of the conductive post 131. Thereafter, a portion of the protective layer 121 is removed to reduce the thickness of the protective layer 121 so that at least a portion of the conductive post 131 protrudes outwardly (FIG. 8). This process of removing the protective layer 121 may utilize a process used in a photolithography process in the art. Thereafter, a mask 200 is formed to expose the upper surface of the conductive post 131 (FIG. 9). The mask 200 may use, for example, dry film resist (DFR) and may expose a region in which the conductive post 131 is formed through an exposure and development process. Thereafter, the insulating film 141 on which the conductive post 131 is formed on an upper surface thereof is removed (FIG. 10), and dry etching, wet etching, or the like known in the art may be used. Thereafter, the mask 200 is removed to obtain the printed circuit board 100 having the form illustrated in FIG. 3.

Among the other operations, the same components as those of the method of manufacturing a printed circuit board according to an example or the method of manufacturing a printed circuit board according to another example may be applied to the printed circuit board according to another example, and thus, a redundant description thereof is omitted.

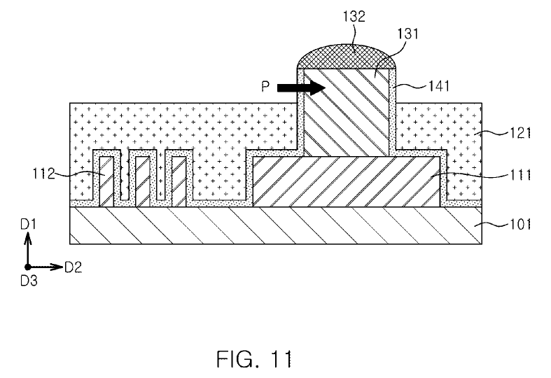

A modified embodiment will be described with reference to FIG. 11. In the case of the modified example of FIG. 11, a conductive cap layer 132 may be further included to more effectively protect the conductive post 131 and improve electrical connectivity. Specifically, the conductive cap layer 132 is disposed on the conductive post 131 and is electrically connected to the conductive post 131. In this case, due to the presence of the insulating film 141, the conductive cap layer 132 may be formed in a range not covering the side surface of the conductive post 131. Furthermore, as illustrated, the conductive cap layer 132 may be formed in a range not covering the side surface of the insulating film 141. In this case, a width of the conductive post remains substantially the same after forming the conductive cap 132 compared to a width of the conductive post before forming the conductive cap 132.

In the case of the printed circuit board according to an example of the present disclosure, the structural stability of the conductive post, or the like may be improved.

In the present disclosure, a cross-section may refer to a cross-sectional shape when an object is cut vertically, a cross-sectional shape when an object is cut vertically, or a cross-sectional shape when an object is viewed from a side view. In addition, “on a plane” may refer to a planar shape when an object is cut horizontally or a planar shape when an object is viewed from a top-view or bottom-view.

In this disclosure, the terms upper side, upper portion, upper surface, etc. are used for convenience to refer to a direction toward a surface on which electronic components may be mounted based on the cross-section of the drawings, and the terms lower side, lower portion, lower surface, etc. are used in the opposite direction. However, this is defined as a direction for convenience of description and the scope of the claims is not specifically limited by the description of such directions.

In the present disclosure, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” In addition, it may be understood that when an element is referred to with “first” and “second,” the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The expression “an embodiment or one example” used in the present disclosure does not refer to identical examples and is provided to stress different unique features between each of the examples. However, examples provided in the following description are not excluded from being associated with features of other examples and implemented thereafter. For example, even if matters described in a specific example are not described in a different example thereto, the matters may be understood as being related to the other example, unless otherwise mentioned in descriptions thereof.

The terms used herein are for the purpose of describing particular embodiments only and are not intended to limit the embodiments. As used herein, the singular forms "a,” "an" and "the" are intended to include the plural forms as well, unless the context clearly indicates otherwise.

As used herein, the expression “approximately the same value” may refer to having the same value relative to other value(s) compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ± 1%, ± 5% , or ± 10% of the actual value stated, and other suitable tolerances.

What is claimed is:

1. A printed circuit board comprising:
an insulating layer;
a pad portion disposed on the insulating layer;
a protective layer disposed on the insulating layer and the pad portion;
a conductive post disposed on the pad portion and protruding outwardly, as compared to the protective layer; and
an insulating film formed on a portion of a surface of the conductive post.

2. The printed circuit board of claim 1, wherein at least a portion of the insulating film is interposed between the conductive post and the protective layer.

3. The printed circuit board of claim 1, wherein the insulating film is in contact with the conductive post and the protective layer.

4. The printed circuit board of claim 1, wherein the insulating film is formed in at least a portion of a side surface of the conductive post not covered with the protective layer.

5. The printed circuit board of claim 1, wherein at least a portion of an upper surface of the conductive post is exposed and not covered with the insulating film.

6. The printed circuit board of claim 1, wherein the insulating film is also formed on a surface of the pad portion.

7. The printed circuit board of claim 1, further comprising a conductive layer disposed on the insulating layer, and the insulating film is also formed on a surface of the conductive layer.

8. The printed circuit board of claim 1, wherein the insulating film is also formed on an upper surface of the insulating layer.

9. The printed circuit board of claim 1, wherein the insulating film extends to surfaces of the pad portion and the insulating layer to form an integral structure as a whole.

10. The printed circuit board of claim 9, wherein the insulating film has a shape conforming to the surface of the conductive post, the pad portion, and the insulating layer.

11. The printed circuit board of claim 1, wherein the insulating film is an atomic layer deposition layer.

12. The printed circuit board of claim 1, wherein the insulating film includes Al₂O₃.

13. The printed circuit board of claim 1, further comprising:
a conductive cap layer disposed on the conductive post and electrically connected to the conductive post.

14. The printed circuit board of claim 13, wherein the conductive cap layer is formed in a range not covering a side surface of the conductive post.

15. The printed circuit board of claim 13, wherein the conductive cap layer is formed in a range not covering a side surface of the insulating film.

16. The printed circuit board of claim 13, wherein a width of the conductive post remains substantially the same after forming the conductive cap.

17. A printed circuit board comprising:
an insulating layer;
a pad portion disposed on the insulating layer;
a protective layer disposed on the insulating layer and the pad portion;
a conductive post disposed on the pad portion; and
an insulating film formed on a portion of surfaces of the pad portion and the conductive post.

18. The printed circuit board of claim 17, wherein the insulating film is a surface oxide layer of the conductive post.

19. The printed circuit board of claim 17, wherein an upper surface of the conductive post is exposed and configured to provide an electrical connection to an electronic component.

20. The printed circuit board of claim 17, further comprising:
a conductive cap layer disposed on the conductive post and electrically connected to the conductive post.
